(19) United States
(12) Patent Application Publication
(10) Pub. No.: US 2023/0018510 A1
(43) Pub. Date: Jan. 19, 2023

(54) SOCKET AND TOOL

(71) Applicant: YOKOWO CO., LTD., Kita-ku, Tokyo (JP)

(72) Inventors: Kohei AMADA, Tomioka-shi, Gunma (JP); Yuki MATSUI, Tomioka-shi, Gunma (JP); Yoshinori SHIRAI, Tomioka-shi, Gunma (JP); Suguru MATSUI, Tomioka-shi, Gunma (JP)

(73) Assignee: YOKOWO CO., LTD., Kita-ku, Tokyo (JP)

(21) Appl. No.: 17/777,636

(22) PCT Filed: Nov. 2, 2020
(86) PCT No.: PCT/JP2020/041094

§ 371 Date: May 18, 2022

(30) Foreign Application Priority Data
Nov. 21, 2019 (JP) 2019-210244

(51) Int. Cl. G01R 1/04; H01R 43/22

(52) U.S. Cl. CPC G01R 1/0466; H01R 43/22

(57) ABSTRACT

A socket includes a pin block on which a plurality of contact probes are installed, a pin plate configured to hold the plurality of contact probes together with the pin block, and an engagement portion configured to engage the pin block and the pin plate with each other. The engagement portion is configured to detachably engage the pin block and the pin plate with each other.

### TECHNICAL FIELD

The present invention relates to a socket used for inspection of an integrated circuit (IC) package.

### BACKGROUND ART

There is known a socket used for inspection of an IC package (see, for example, Patent Literature 1).

The socket includes a pin block on which a plurality of contact probes corresponding, one to one, to electrode terminals of an IC are erected, and a guide member provided above the pin block. When the IC package to be inspected is inserted into the guide member in a posture where the electrode terminals face downward, the IC package is guided onto the contact probes in a predetermined posture. By appropriately pressing the IC package from an upper side to a lower side, the electrode terminals of the IC package come into contact with the contact probes, and thus an electric conduction path for inspection is secured.

### CITATION LIST

### Patent Literature

Patent Literature 1: JP-A-2016-207511

### SUMMARY OF INVENTION

### Technical Problem

In order to improve high-frequency characteristics in electric connection, when a total length of a contact probe is shortened, it is required to reduce thickness of a socket holding the contact probe. Then, a holding structure of a pin block, a pin plate, and the like constituting the socket is also required to be adapted thereto.

An example of object of the present invention is to achieve a contact probe holding structure adapted to thickness reduction of a socket.

### Solution to Problem

According to an aspect of the present invention, a socket includes a pin block on which a plurality of contact probes are installed, a pin plate configured to hold the plurality of contact probes together with the pin block, and an engagement portion configured to engage the pin block and the pin plate with each other.

According to the aspect of the present invention, it is possible to achieve the contact probe holding structure adapted to the thickness reduction of the socket.

### BRIEF DESCRIPTION OF DRAWINGS

FIG. 1 is an external view showing a configuration example of a socket according to a first embodiment.

FIG. 2 is a bottom view of a pin block according to the first embodiment.

FIG. 3 is a cross-sectional view taken along line III-III of FIG. 2.

FIG. 4 is a top view of a pin plate according to the first embodiment.

FIG. 5 is a cross-sectional view taken along line V-V of FIG. 4.

FIG. 6 is a perspective external view showing a configuration example of a tool according to the first embodiment (part 1).

FIG. 7 is a perspective external view showing the configuration example of the tool according to the first embodiment (part 2).

FIG. 8 is a perspective external view of a left half body and a fulcrum shaft.

FIG. 9 is a view showing assembly of the pin block and the pin plate according to the first embodiment (part 1).

FIG. 10 is a view showing the assembly of the pin block and the pin plate according to the first embodiment (part 2).

FIG. 11 is a view showing the assembly of the pin block and the pin plate according to the first embodiment (part 3).

FIG. 12 is an enlarged perspective view of an engagement portion during assembly.

FIG. 13 is an enlarged perspective view of the engagement portion when assembly is completed.

FIG. 14 is a bottom view of the pin block and the pin plate when assembly is completed in the first embodiment.

FIG. 15 is a cross-sectional view taken along line XV-XV of FIG. 14.

FIG. 16 is an exploded view showing a configuration example of a pin block and a pin plate according to a second embodiment.

FIG. 17 is an enlarged perspective cross-sectional view around an engagement hook portion and an engagement protrusion portion during assembly of the second embodiment.

FIG. 18 is an enlarged perspective cross-sectional view around the engagement hook portion and the engagement protrusion portion in a state where assembly of the second embodiment is completed.

FIG. 19 is a perspective view showing a configuration example of a pin block and a pin plate according to a third embodiment.

FIG. 20 is a perspective external view showing a configuration example of a press-fit pin.

FIG. 21 is an enlarged cross-sectional view showing a connection portion between a block-side press-fit hole and a plate-side press-fit hole (part 1).

FIG. 22 is an enlarged cross-sectional view showing the connection portion between the block-side press-fit hole and the plate-side press-fit hole (part 2).

### DESCRIPTION OF EMBODIMENTS

Examples of preferred embodiments of the present invention will be described. However, modes to which the present invention can be applied are not limited to the following embodiments. Three orthogonal axes for indicating common directions in the drawings are shown. The three orthogonal axes are right-handed axes, among which a positive direction of the Z-axis is an upward direction.

### First Embodiment

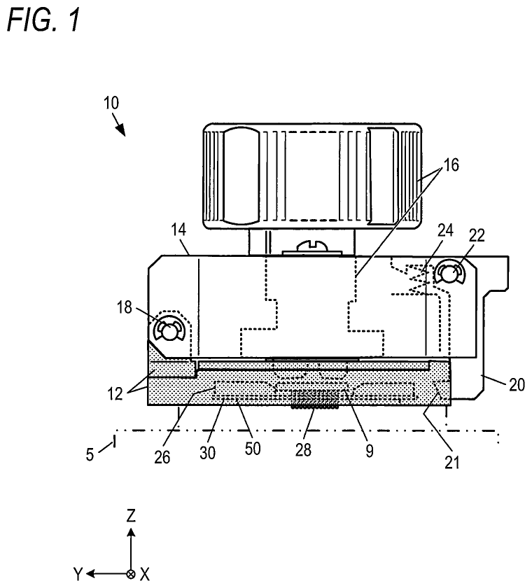

FIG. 1 is an external view showing a configuration example of a socket 10 of the present embodiment. The socket 10 includes a socket body 12, a lid body 14, and a pressing mechanism 16.

The socket body 12, in which an inspection target IC package 9 is inserted, is mounted on an inspection device 5.

The lid body 14 is swingably supported by a lid body swing shaft 18 along the X-axis direction, and supports the pressing mechanism 16 above the socket body 12.

The pressing mechanism 16 applies a load from an upper side to a lower side to the inspection target IC package 9 inserted into the socket body 12.

A hook 20 is provided on a negative side in the Y-axis direction (right direction when viewed from the front of the paper of FIG. 1), which is a side opposite to the side where the lid body swing shaft 18 is provided on the lid body 14. The hook 20 is swingably supported by a hook swing shaft 22 along the X-axis direction, and is urged at the hook swing shaft 22 by a coil spring 24 in a clockwise direction when viewed from a negative side in the X-axis direction.

When an engagement claw 21 is engaged with the socket body 12, the hook 20 maintains a state where the lid body 14 covers an upper side of the socket body 12. When the hook 20 is detached by releasing the urged state by the hook swing shaft 22 and the lid body 14 is swung at the lid body swing shaft 18, an inside of the socket body 12 is exposed, and the inspection target IC package 9 can be taken in and out.

The socket body 12 includes a guide member 26, a contact probe array 28, a pin block 30, and a pin plate 50.

The guide member 26 guides the inspection target IC package 9 such that the inspection target IC package 9 inserted into the socket body 12 is located at a predetermined relative position in a predetermined posture relative to the contact probe array 28.

The contact probe array 28 is constituted by arranging a plurality of contact probes along an XY plane so as to correspond to an arrangement of electrode terminals of the inspection target IC package 9. Each contact probe of the contact probe array 28 is held by the pin block 30 and the pin plate 50 such that a longitudinal direction thereof is along the Z-axis direction.

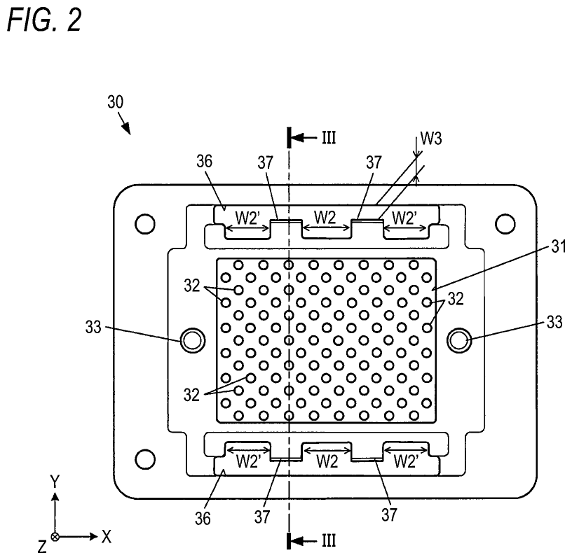

FIG. 2 is a bottom view of the pin block 30.

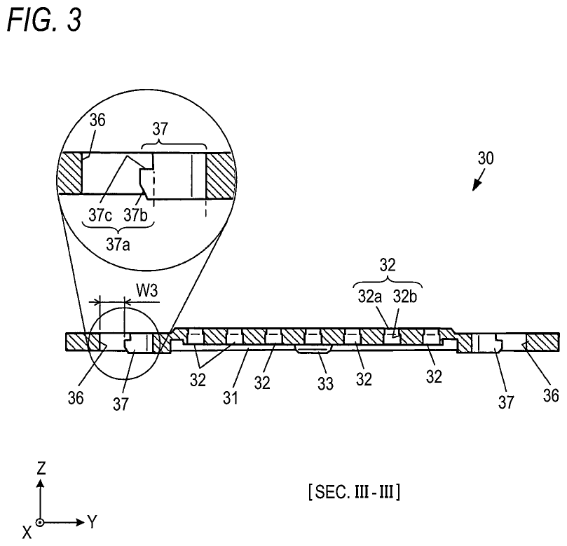

FIG. 3 is a cross-sectional view taken along line III-III of FIG. 2.

The pin block 30 is a component made of an insulating elastic resin. The pin block 30 includes a central recessed portion 31 in a central portion of a bottom surface thereof (side surface in a negative direction of the Z-axis), and includes a plurality of probe insertion portions 32 in a ceiling portion of the central recessed portion 31. The probe insertion portions 32 are portions corresponding, one to one, to the contact probes constituting the contact probe array 28, and function to hold upper ends of the inserted contact probes relative to the pin block 30.

Each probe insertion portion 32 includes a through hole 32a in an up-down direction (Z-axis direction), and includes a step portion 32b around the through hole 32a (see FIG. 3). A plunger of the contact probe penetrates the pin block 30 through the through hole 32a. A barrel (larger in diameter than the plunger) of the contact probe is abutted against the step portion 32b and thus the upper end of the contact probe is positioned and held relative to the pin block 30.

The pin block 30 includes positioning portions 33 on an X-axis positive side and the X-axis negative side, respectively, with the central recessed portion 31 interposed therebetween. Each positioning portion 33 is a protrusion protruding downward (in the negative direction of the Z-axis). The positioning portion 33 functions to position the pin plate 50 relative to the pin block 30 and to prevent positional misalignment of the pin plate 50 relative to the pin block 30 when the pin block 30 and the pin plate 50 are assembled by fitting the positioning portion 33 into a positioning hole 56, which will be described later, provided in the pin plate 50.

The pin block 30 includes engagement holes 36 that are elongated along the X-axis direction and that have a comb shape in a top view on outer sides on a Y-axis positive side and the Y-axis negative side with the central recessed portion 31 interposed therebetween. Two engagement protrusion portions 37 are provided on an inner side surface of each engagement hole 36 on the side of the contact probe array 28 so as to extend outward along the Y-axis. Since the engagement protrusion portions 37 are provided at a predetermined interval along the X-axis, the engagement hole 36 has a comb tooth shape when viewed in a bottom view.

Each engagement protrusion portion 37 includes an engagement claw portion 37a at a tip end portion of an extended portion. The engagement claw portion 37a includes a tapered portion 37b on a lower portion thereof and a step portion 37c on an upper portion thereof (see FIG. 3). The engagement protrusion portion 37 constitutes a part of a coupling portion 60 that detachably couples the pin block 30 and the pin plate 50 with each other.

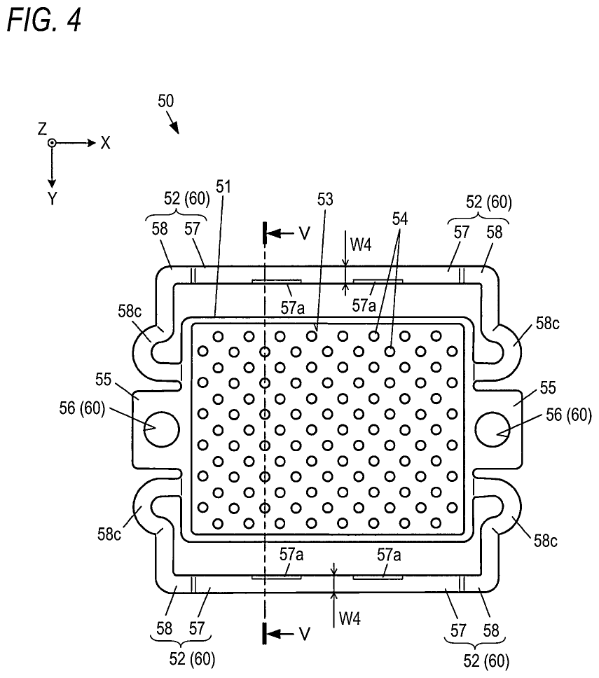

FIG. 4 is a top view of the pin plate 50.

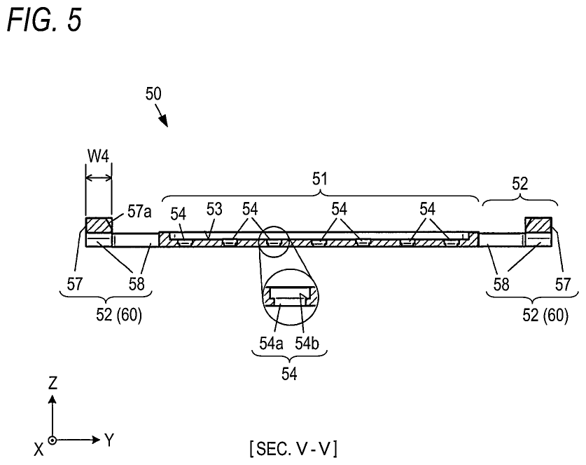

FIG. 5 is a cross-sectional view taken along line V-V of FIG. 4.

The pin plate 50 is a component made of an insulating elastic resin. The pin plate 50 is mounted on the bottom surface of the pin block 30, passes through each through hole 32a of the pin block 30, and holds a lower end of each contact probe of the contact probe array 28 held by the pin block 30. The pin plate 50 includes an inner region portion 51, an outer region portion 52, and an extension portion 55.

The inner region portion 51 includes a central recessed portion 53 that is recessed such that an up-down thickness thereof is thinner than that of an outer edge of the inner region portion 51. The central recessed portion 53 is opened upward (in the positive direction of the Z-axis) and has a flat bottom surface. The central recessed portion 53 is provided with a plurality of probe insertion portions 54 corresponding to the respective contact probes of the contact probe array 28.

The probe insertion portions 54 correspond, one to one, to the contact probes constituting the contact probe array 28. When the lower end of each contact probe is inserted into each probe insertion portion 54, the probe insertion portion 54 functions to hold the lower end of the inserted contact probe relative to the pin plate 50.

Each probe insertion portion 54 includes a through hole 54a in the up-down direction, and includes a step portion 54b around the through hole 54a (see FIG. 5). The plunger of the contact probe penetrates the pin plate 50 through the through hole 54a. The barrel (larger in diameter than the plunger) of the contact probe is abutted against the step portion 54b and thus the lower end of the contact probe is positioned and held relative to the pin plate 50.

The outer region portion 52 is provided on each of the Y-axis positive side and the Y-axis negative side of the inner region portion 51. A strip-shaped portion having a rectangular cross-section of the outer region portion 52 on the Y-axis positive side passes through a position separated from a Y-axis positive side surface of the inner region portion 51 and is connected to an X-axis positive side surface of the inner region portion 51 and an X-axis negative side surface of the inner region portion 51. Similarly, a strip-shaped portion having a rectangular cross-section of the outer region portion 52 on the Y-axis negative side passes through a position separated from a Y-axis negative side surface of the inner region portion 51 and is connected to the X-axis positive side surface of the inner region portion 51 and the X-axis negative side surface of the inner region portion 51. The outer region portions 52 can also be referred to as outer edge portions separated from the inner region portion 51. The outer region portions 52 are a pair of loop-shaped ear portions forming gaps between the outer region portions 52 and the inner region portion 51.

Each outer region portion 52 includes an engagement hook portion 57 that is a linear portion along the X-axis, and two flexible portions 58 that connect each X-axis direction end portion of the engagement hook portion 57 and the inner region portion 51. The outer region portion 52 constitutes a part of the engagement portion 60 that detachably engages the pin block 30 and the pin plate 50 with each other.

A vertical cross-section of the engagement hook portion 57 is substantially rectangular. As shown in FIG. 5, an engaged portion of the engagement hook portion 57 with which the engagement claw portion 37a of the engagement protrusion portion 37 (see FIGS. 2 and 3) of the pin block 30 is engaged is a tapered portion 57a.

Each flexible portion 58 is a portion whose shape is easily subjected to a bending stress so as to be intentionally elastically deformed more easily than other portions when an external force that displaces the engagement hook portion 57 in a direction away from the inner region portion 51 is applied to the engagement hook portion 57. The flexible portion 58 includes a curved portion 58c that is convex toward the X-axis positive side or the X-axis negative side and that has a semicircular shape in a top view.

A Y-axis direction width W4 of the engagement hook portion 57 is set to be smaller than a width W3 of a narrow width portion in the Y-axis direction of the engagement hole 36 (see FIG. 2) of the pin block 30. When the engagement hook portion 57, which is a linear portion, is inserted into the narrow width portion of the engagement hole 36, the engagement hook portion 57 interferes with the engagement protrusion portion 37. As will be described later, a configuration for reducing such interference is provided in the engagement hook portion 57 and the engagement protrusion portion 37. The width W3 is set such that the engagement claw portion 37a reliably engages with the engagement hook portion 57. A position of the engagement hook portion 57 in the Z-axis direction is set in the up direction (positive direction of the Z-axis) relative to positions of the inner region portion 51 and the flexible portion 58.

The pin plate 50 includes the extension portions 55 that extend in the X-axis direction between a connection portion between the outer region portion 52 on the Y-axis positive side and the inner region portion 51 and a connection portion between the outer region portion 52 on the Y-axis negative side and the inner region portion 51, on each of the X-axis positive side surface and the X-axis negative side surface of the inner region portion 51. Each extension portion 55 includes the positioning hole 56 that penetrates in the up-down direction. An inner diameter of the positioning hole 56 matches an outer shape of the positioning portion 33 (see FIGS. 2 and 3). The positioning hole 56 of the pin plate 50 and the positioning portion 33 of the pin block 30 are fitted to each other, so that the pin plate 50 is positioned relative to the pin block 30, and further, a fitting relationship thereof prevents positional misalignment of the pin plate 50 relative to the pin block 30.

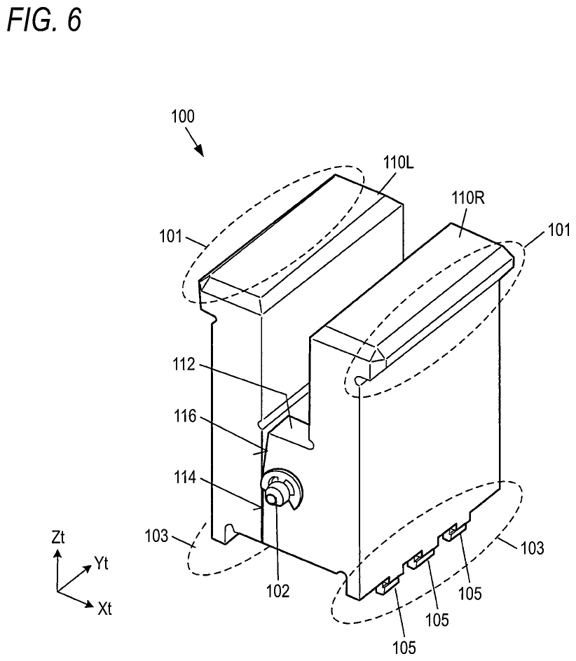

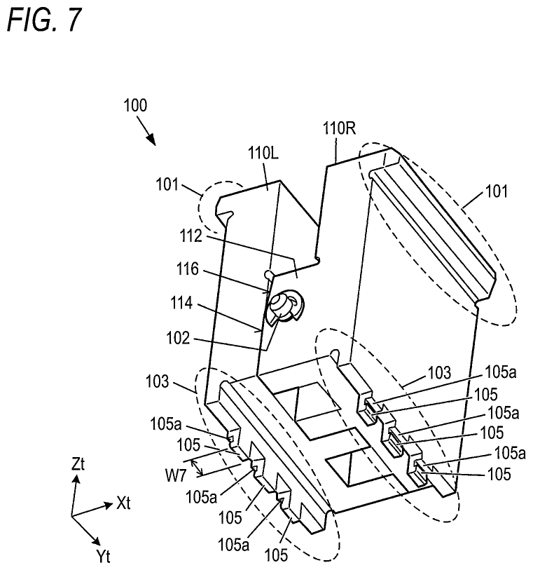

FIG. 6 is a perspective external view showing a configuration example of a tool 100 used when the pin block 30 and the pin plate 50 are assembled, which corresponds to an external view in which the tool 100 is viewed obliquely from above. FIG. 7 is also a perspective external view, which corresponds to an external view in which the tool 100 is viewed obliquely from below. Three orthogonal axes, namely Xt, Yt and Zt shown in FIGS. 6 and 7, are right-handed coordinates indicating up, down, left, and right for the tool 100. As compared with the three orthogonal axes X, Y, and Z shown in the drawings related to the socket 10 in FIGS. 1 to 5, Xt, Yt and Zt are reversed in the up-down direction.

The dedicated tool 100 is used for assembling and disassembling the pin plate 50 relative to the pin block 30. The tool 100 has a structure in which a pair of handles 101 is pinched or opened by two fingers of an operator to widen or reduce a distance between a pair of tip end portions 103 while a fulcrum shaft 102 serves as a fulcrum.

The tool 100 includes the fulcrum shaft 102 provided along the Yt-axis direction, a right half body 110R, and a left half body 110L.

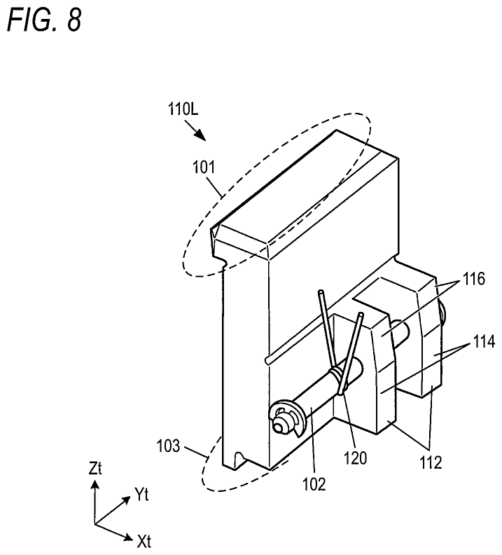

FIG. 8 is a perspective external view of the left half body 110L and the fulcrum shaft 102.

As shown in FIGS. 7 and 8, the left half body 110L includes one of the handles 101, one of the tip end portions 103, and a bearing portion 112 that includes an insertion hole through which the fulcrum shaft 102 is inserted.

Each tip end portion 103 includes three key claw portions 105 that protrude downward in a posture where claw protrusions thereof face outward in a left-right direction (Xt-axis direction orthogonal to an axial direction of the fulcrum shaft 102). Each key claw portion 105 includes a flat portion 105a. The flat portion 105a is located above each claw protrusion (in the Zt-axis direction), and is wide in the Xt-axis direction where the claw protrusion faces.

An installation interval between the three key claw portions 105 is set in accordance with an installation interval between the engagement protrusion portions 37 of the engagement holes 36 of the pin block 30. A Yt-axis direction width W7 (see FIG. 7) of each key claw portion 105 is set to be smaller than a distance W2 between the two engagement protrusion portions 37 of the engagement holes 36 of the pin block 30 and a width W2′ of a gap provided on a side opposite to the distance W2 with the two engagement protrusion portions 37 interposed therebetween (see FIG. 2).

The bearing portion 112 includes a first abutment surface 114 and a second abutment surface 116.

The first abutment surface 114 shown in FIG. 8 is a surface parallel to an inner side surface of the right half body 110R in a state where the tool 100 is closed (state where the pair of handles 101 are farthest from each other), and is abutted against the inner side surface in the parallel state. Meanwhile, the first abutment surface 114 is a surface rotated by the fulcrum shaft 112 to form a predetermined angle (angle larger than 0°) with the inner side surface of the right half body 110R in a state where the tool 100 is opened (state where the pair of handles 101 are closest to each other), and a gap is formed between the first abutment surface 114 and the inner side surface (the first abutment surface 114 does not abut against the inner side surface) in the state where the predetermined angle is formed.

The second abutment surface 116 shown in FIG. 8 is a surface that forms a predetermined angle (angle larger than 0°) with the inner side surface of the right half body 110R in the state where the tool 100 is closed (state where the pair of handles 101 are farthest from each other), and a gap is formed between the second abutment surface 116 and the inner side surface in the state where the predetermined angle is formed. Meanwhile, the second abutment surface 116 is a surface that is rotated by the fulcrum shaft 112 and abutted against the inner side surface of the right half body 110R in the state where the tool 100 is opened (state where the pair of handles 101 are closest to each other). The second abutment surface 116 functions as a limiting portion that limits an approaching distance between the pair of handles by abutment against the inner side surface of the right half body 110R.

By setting the predetermined angle as described above, it is possible to limit the distance at which the pair of handles 101 are farthest from each other. Forcibly, a distance by which the engagement hook portion 54 to be described later is expanded can be limited.

Although the first abutment surface 114 and the second abutment surface 116 of the left half body 1101 are described in FIG. 8, the right half body 110R also includes two abutment surfaces corresponding to the abutment surface 114 and the second abutment surface 116, which have the same function.

An urging portion 120 is attached to the fulcrum shaft 102. In the example of FIG. 8, the urging portion 120 includes a twisted portion at substantially a center of the fulcrum shaft 102 and two urging rods extending upward from the twisted portion. When the tool 100 is assembled, the two urging rods of the urging portion 120 urge the left half body 110L and the right half body 110R in a direction in which the distance between the pair of handles 101 is widened (a direction in which the pair of tip end portions 103 approach each other). Although the urging portion 120 is exemplified as a torsion spring including the twisted portion and the two urging rods in the example of FIG. 8, the urging portion 120 is not limited thereto, and may be, for example, a plate spring.

The right half body 110R includes the other handle 101 and the other tip end portion 103, and includes three key claw portions 105 on the other tip end portion 103, while an arrangement position of the bearing portion 112 thereof is different from that of the left half body 110L. Such components have the same shapes as those of the left half body 110L, except that the arrangement position of the bearing portion 112 is different from that of the left half body 110L.

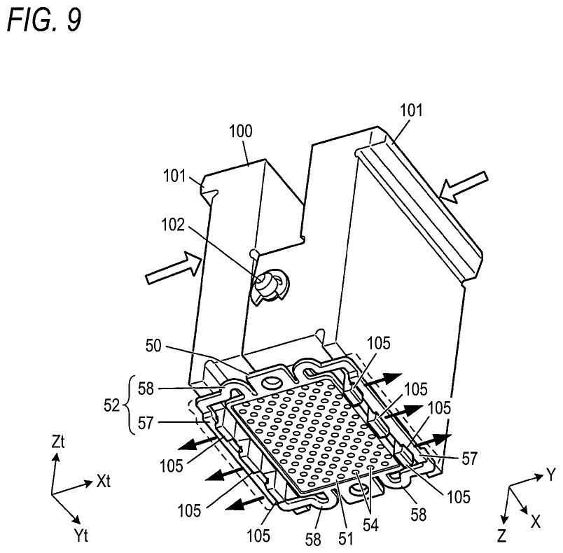

FIG. 9 is a view showing assembly of the pin block 30 and the pin plate 50, which corresponds to a perspective view of the tool 100 as viewed from obliquely below the tool. The three orthogonal axes, namely Xt, Yt, and Zt, are coordinate systems based on up, down, left, and right directions relative to the tool 100, while the three orthogonal axes, namely X, Y, and Z, are coordinate systems based on up, down, left, and right directions relative to the pin block 30 and the pin plate 50 (up, down, left, and right directions relative to the socket 10). The same applies to the subsequent drawings.

First, as shown in FIG. 9, the operator attaches the pin plate 50 to the tip end portion 103 of the tool 100. Specifically, the operator directs a bottom surface of the pin plate 50 toward the tool 100, and inserts the tip end portion 103 of the tool 100 into a gap between the inner region portion 51 and the outer region portion 52 of the pin plate 50. Then, by pressing the bottom surface of the pin plate 50 in a direction opposite to the Zt-axis direction by the flat portion 105a of the key claw portion 105, the key claw portion 105 (claw protrusion) of the tip end portion 103 is engaged with the engagement hook portion 57. The operator clamps the pair of handles 101 with two fingers in the same way as opening a clothespin such that the pair of handles 101 approach each other (so as to move the pair of handles 101 in a direction indicated by a white arrow in FIG. 9).

A force that reduces the distance between the pair of handles 101 (force applied in the direction indicated by the white arrow in FIG. 9) is applied as a force that widens the distance between the pair of tip end portions 103 by the fulcrum shaft 102 (force applied in a direction indicated by a black thick arrow in FIG. 9). As a result, the key claw portion 105 engaged with the engagement hook portion 57 widens the gap between the inner region portion 51 and the outer region portion 52 of the pin plate 50.

The force that widens the distance between the pair of tip end portions 103 is applied as an external force that separates the engagement hook portion 57 from the inner region portion 51 via the three key claw portions 105.

Since the flat portion 105a of each key claw portion. 105 is pressed against the pin plate 50 such that the key claw portion 105 (claw protrusion) is engaged with the engagement hook portion 57, the pin plate 50 can be reliably held by the tool 100.

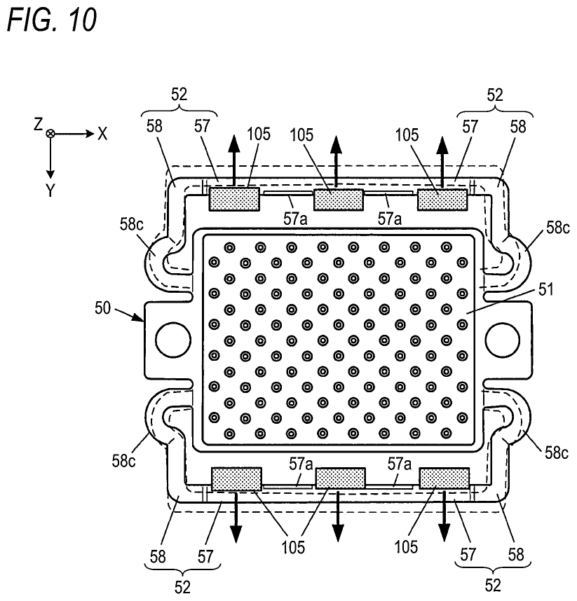

FIG. 10 is a view of the pin plate 50 attached to the tool 100 as viewed from a tip end side of the tool 100. Regarding the outer region portion 52, a solid line indicates a state before the distance between the tip end portions 103 of the tool 100 is widened, and a long dashed line indicates a state after the distance between the tip end portions 103 of the tool 100 is widened. However, in order to facilitate understanding, bending and displacement are shown in an exaggerated manner. Each tip end portion 103 (key claw portion 105) is shown in a hatched manner in order to facilitate identification.

The key claw portion 105 is abutted against a side surface of the engagement hook portion 57 on the side of the inner region portion 51, and a force is applied to a predetermined portion of the engaged pin plate 50 (engagement hook portion 57 on the side of the inner region portion 51), so that an elastic portion (flexible portion 58) of the pin plate 50 is elastically deformed. The tool 100 holds the pin plate 50 in a state where the engagement hook portion 57 reaches the long dashed line.

An external force applied to the engagement hook portion 57 via the key claw portion 105 (force applied in the direction of the black thick arrow in FIG. 10) causes bending of the pin plate 50. However, since the flexible portion 58 is provided on the outer region portion 52, the flexible portion 58 is bent to absorb the external force. Specifically, curvature of the curved portion 58c that is curved in a semicircular shape in a bottom view is reduced, and bending is induced in such a manner that an arc of the curve is extended. Therefore, influence of bending of the inner region portion 51 caused by the external force is negligibly small.

Since the inner region portion 51 is not bent, shapes of the probe insertion portions 54 and a positional relationship between adjacent probe insertion portions 54 do not change. As a result, the contact probes of the contact probe array 28 can be correctly inserted into the pin plate 50. No excessive force is applied to the contact probes in the direction of the XY plane.

Next, as shown in FIG. 11, the operator assembles the pin plate 50 to the pin block 30 in a state where the distance between the pair of handles 101 is reduced and the distance between the tip end portions 103 is widened.

Specifically, the pin plate 50 is temporarily fixed to a predetermined assembly jig 200 in a state where the pin plate 50 is turned upside down, and each corresponding contact probe is assembled to each probe insertion portion 54. In the pin block 30 temporarily fixed to the assembly jig 200, since the positioning portion 33 is directed upward (see FIG. 2), the operator tits the positioning hole 56 (see FIG. 4) of the pin plate 50 into the positioning portion 33 and assembles the pin plate 50 so as to cover the pin block 30.

When the positioning hole 56 and the positioning portion 33 are fitted to each other, the pin block 30 and the pin plate 50 have a correct relative positional relationship, and thus the through hole 32a of each probe insertion portion 32 of the pin block 30 and the through hole 54a of each probe insertion portion 543 of the pin plate 50 have a correct positional relationship. In the process of assembling the pin plate 50 so as to cover the pin block 30, each contact probe of the contact probe array 28 is smoothly inserted into each probe insertion portion 54 of the pin plate 50.

FIG. 12 is an enlarged perspective view of the engagement portion 60 (engagement hook portion 57 and engagement protrusion portion 37) between the pin block 30 and the pin plate 50 during assembly, and is an enlarged view showing a periphery of the key claw portion 105 of the tool 100 in an enlarged manner in the process of assembling the pin plate 50 so as to cover the pin block 30. In order to facilitate identification, the pin plate 50 is hatched.

As described above, the force that reduces the distance between the pair of handles 101 is applied as the external force that widen the distance between the pair of tip end portions 103 by the fulcrum shaft 102. Therefore, in the pin plate 50 in the assembly process, the engagement hook portion 57 is separated from the inner region portion 51 as compared with a free state where no external force is applied. The position of the engagement hook portion 57 in the Z-axis direction is above (in the positive direction of the Z-axis) the engagement hole 36 (see FIGS. 2 and 3).

In the process of assembling the pin plate 50 so as to cover the pin block 30, the engagement hook portion 57 is positioned above (substantially directly above) a gap portion (gap having the width W3 shown in FIGS. 2 and 3) where a facing distance with the engagement protrusion portion 37 (width in the Y-axis direction) is the narrowest in the engagement hole 36. In addition, at the same time, the key claw portion 105 of the tool 100 engaged with the engagement hook portion 57 is positioned above a gap (gap having the width W2′ shown in FIG. 2) in the engagement hole 36 where the engagement protrusion portion 37 is not provided to protrude therefrom.

In this state, when the operator presses the pin plate 50 together with the tool 100 against the pin block 30, the tapered portion 57a (see FIG. 5) of the engagement hook portion 57 and the tapered portion 37b (see FIG. 3) of the engagement protrusion portion 37 are abutted against with each other, and are both elastically bent while being in sliding contact with each other. The engagement hook portion 57 is displaced outward due to bending of the flexible portion 58, and the tip end of the engagement protrusion portion 37 is bent and slightly hangs down. Due to displacement of the engagement protrusion portion 37 and the engagement hook portion 57, the engagement hook portion 57 is guided into the gap where the width in the Y-axis direction is the narrowest for the engagement hole 36 without hardship.

Then, the engagement hook portion 57 and the tip end portion 103 (key claw portion 105) of the tool 100 pass through the engagement hole 36 and reach a front surface side of the pin block 30 (side opposite to the tool 100 when viewed in a state of being fixed to the assembly jig 200). At the same time (or one after the other), the central recessed portion 53 (see FIG. 5) of the inner region portion 51 of the pin plate 50 is fitted into the central recessed portion 31 (see FIGS. 2 and 3) of the pin block 30. This state is the state shown in FIG. 12.

Next, the operator releases the force that reduces the distance between the pair of handles 101. Due to an action of the urging portion 120 (see FIG. 8), the distance between the tip end portions 103 of the tool 100 is naturally reduced, the first abutment surface 114 of the left half body 110L is abutted against the inner side surface of the right half body 110R, and the first abutment surface 114 of the right half body 110R is abutted against an inner side surface of the left half body 110L. As a result, engagement between the key claw portion 105 and the engagement hook portion 57 is released. The tool 100 releases the holding of the pin plate 50 by releasing the force applied to the predetermined portion (engagement hook portion 57) of the pin plate 50 and releasing the engagement between the key claw portion 105 and the engagement hook portion 57. Then, the operator lifts the tool 100 and separates the tool 100 from the pin plate 50. Since the pin block 30 is temporarily fixed to the assembly jig 200 and the pin plate 50 is assembled to the pin block 30, workability is improved.

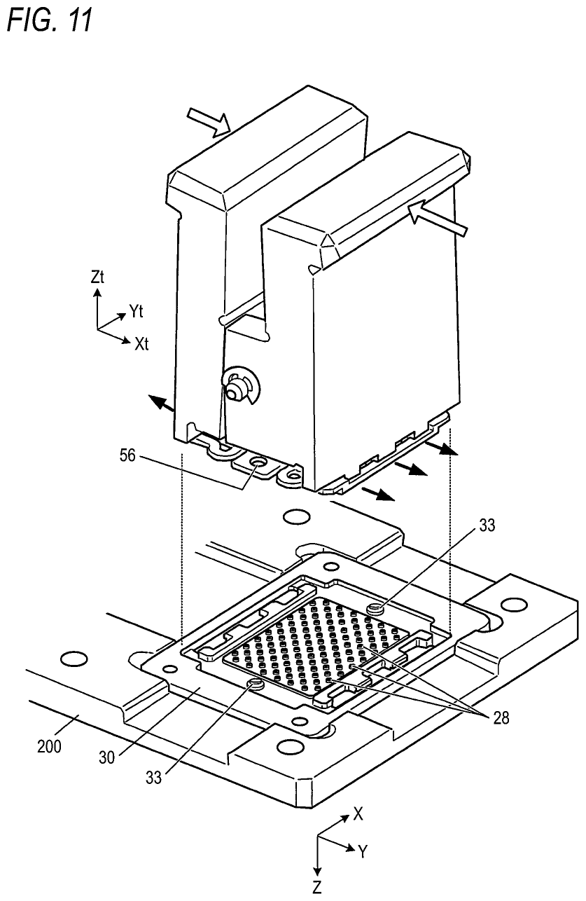

FIG. 13 is an enlarged perspective view of the engagement portion when assembly is completed, which shows a state where the tool 100 is separated from the pin plate 50 in an enlarged manner. In order to facilitate identification, the pin plate 50 is hatched.

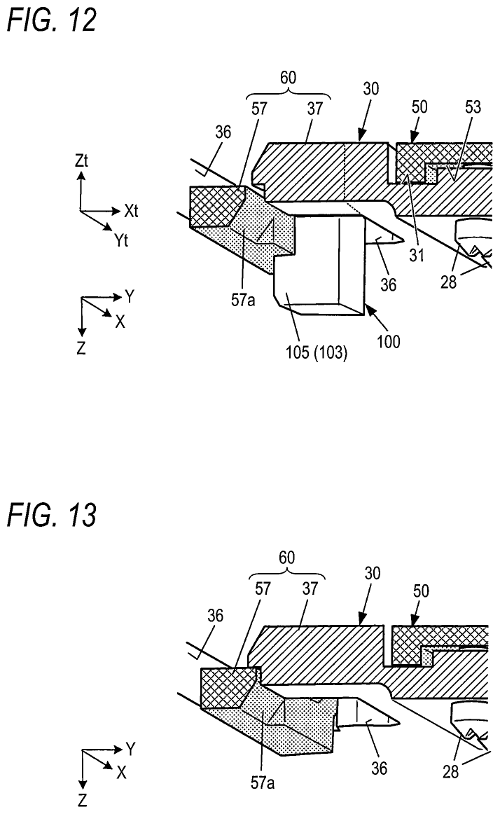

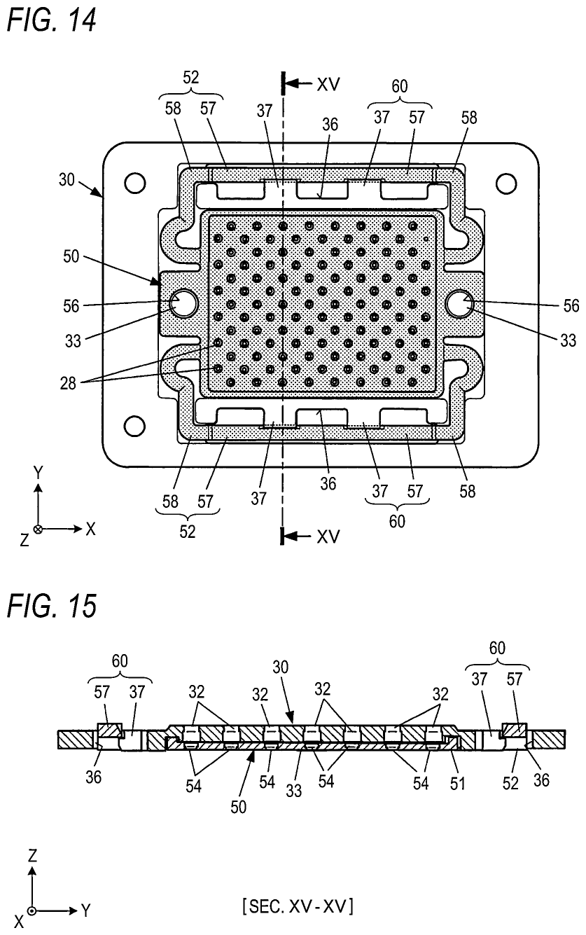

FIG. 14 is a bottom view of the pin block 30 and the pin plate 50 when assembly is completed, which is a view of a state where the tool 100 is lifted and separated from the pin plate 50 as viewed from the side of the tip end portion 103 of the tool 100.

FIG. 15 is a cross-sectional view taken along line XV-XV of FIG. 14. However, illustration of the contact probes is omitted.

When the operator separates the tool 100 from the pin plate 50, on the pin plate 50, since the engagement between the key claw portion 105 and the engagement hook portion 57 is released, there is no external force applied to the engagement hook portion 57, and the bending of the outer region portion 52 is released due to elasticity of the flexible portion 58, and thus the outer region portion 52 returns to the original free state (state shown in FIGS. 4 and 5).

When the outer region portion 52 is in the free state, a corner portion of a back surface of the tapered portion 57a of the engagement hook portion 57 is caught by the step portion 37c (see FIG. 3) of the engagement protrusion portion 37. As a result, the engagement hook portion 57 and the engagement protrusion portion 37 are engaged with each other so as to attach the pin plate 50 to the pin block 30. That is, the engagement hook portion 57 and the engagement protrusion portion 37 function as the engagement portion 60 that engages the pin block 30 and the pin plate 50 with each other.

When the pin plate 50 is detached from the pin block 30, the above-described procedure using the tool 100 may be performed in reverse order. When detaching the pin plate 50 from the pin block 30, the operator inserts the tip end portion 103 of the tool 100 into the gap between the inner region portion 51 and the outer region portion 52 of the pin plate 50 engaged with the pin block 30, and presses the bottom surface of the pin plate 50 in the direction opposite to the Zt-axis direction by the flat portion 105a of the key claw portion 105 of the tip end portion 103. Then, the key claw portion 105 (claw protrusion) of the tip end portion 103 is engaged with the engagement hook portion 57, and thus the pin plate 50 can be reliably held by the tool 100. As a result, workability is improved.

### Second Embodiment

A second embodiment to which the present invention is applied will be described. The same constituent elements as those of the first embodiment are denoted by the same reference numerals as those of the first embodiment, and redundant description thereof will be omitted.

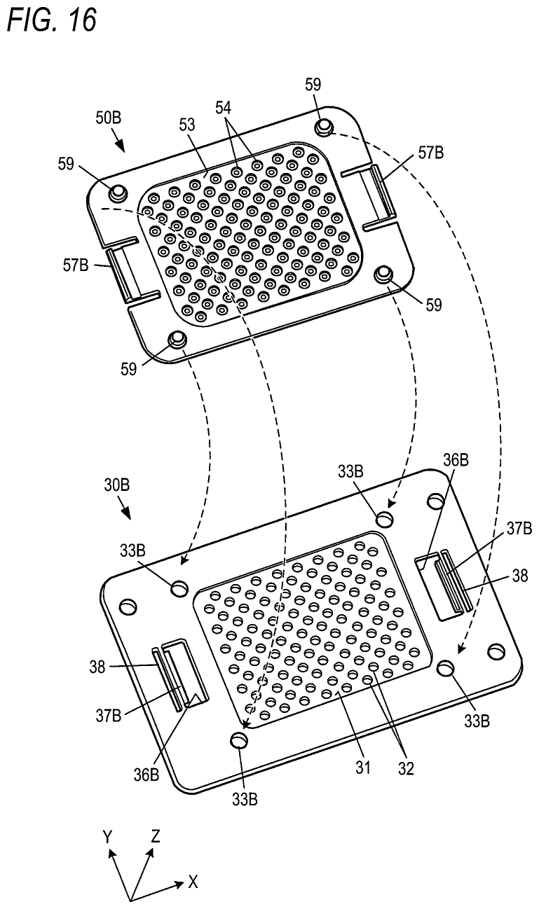

FIG. 16 is an exploded view showing a configuration example of a pin block 30B and a pin plate 50B according to the second embodiment. In FIG. 16, the pin block 30B is shown in a posture where a bottom surface thereof faces the front, and the pin plate 50 is shown in a posture where a top surface thereof faces the front. A coordinate system in FIG. 16 indicates directions corresponding to up, down, left, and right directions of the pin block 30.

The socket 10 of the second embodiment includes the pin block 30B instead of the pin block 30 of the first embodiment, and includes the pin plate 50B instead of the pin plate 50 of the first embodiment.

The pin block 30B is a component made of an insulating elastic resin.

The pin block 30B includes the plurality of probe insertion portions 32 in the ceiling portion of the central recessed portion 31, and includes a positioning portion 33B in an outer peripheral portion of the central recessed portion 31.

The positioning portion 33B is a through hole that is provided to penetrate in the up-down direction at a position facing a positioning protrusion 59 provided on the top surface of the pin plate 50B. An inner diameter of the positioning portion 33B is set to have a fitting relationship with an outer diameter of the positioning protrusion 59, the fitting relationship being sufficient to position the pin plate 50 relative to the pin block 30 and to further function to prevent positional misalignment relative to the pin block 30.

The pin block 30B includes engagement holes 36B on the X-axis positive side and the X-axis negative side in the outer peripheral portion of the central recessed portion 31. Each engagement hole 36B is a hole that has a rectangular shape in a top view and that penetrates in the up-down direction (Z-axis direction). The engagement protrusion portion 37 is provided on an X-axis direction outer side (side opposite to the central recessed portion 31) of the engagement hole 36B. A gap 38 is provided further on the X-axis direction outer side (side opposite to the central recessed portion 31) as compared with the engagement protrusion portion 37.

The pin plate 50B is a component made of an insulating elastic resin.

The pin plate 50B includes the plurality of probe insertion portions 54 in a bottom portion of the central recessed portion 53, and includes the positioning protrusion 59 to be fitted to the positioning portion 33B on an outer peripheral portion of the central recessed portion 53.

On the pin plate 50B, tongue-shaped extension portions 57 are formed on the X-axis positive side and the X-axis negative side on the outer peripheral portion of the central recessed portion 53, and claw-shaped engagement hook portions 57B are provided at tip end portions of the extension portions 57.

Assembly of the pin plate 50B to the pin block 30B is achieved by fitting the positioning protrusion 59 to the positioning portion 33B and pressing the pin plate 50B against the pin block 30B.

Specifically, the operator aligns relative positions of the pin block 30B and the pin plate 50B such that the positioning protrusion 59 is fitted to the positioning portion 33. Then, each engagement hook portion 57B is abutted against an engagement protrusion portion 37B of each engagement hole 36B.

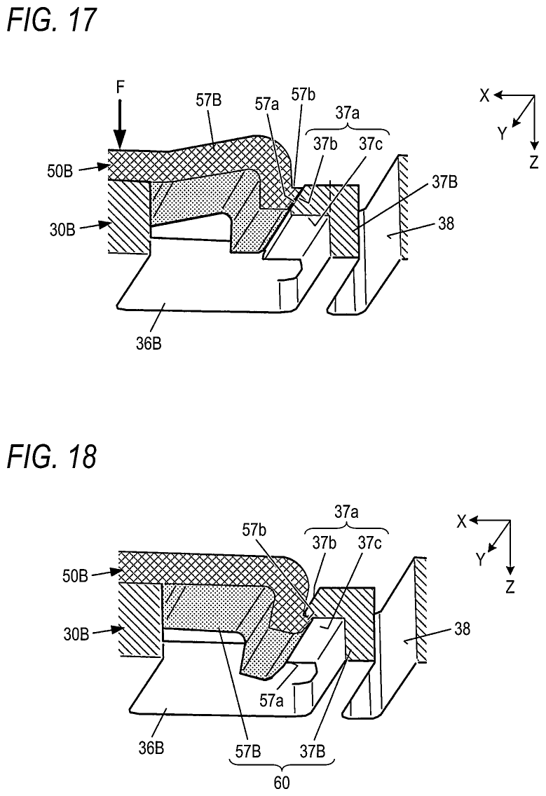

FIG. 17 shows a state where the pin plate 50B starts to be pressed against the pin block 30B, which is an enlarged perspective cross-sectional view around the engagement hook portion 57B and the engagement protrusion portion 37B. Since the operator applies a pressing load from an upper side to a lower side (along a direction indicated by a black thick arrow F in FIG. 17), the upper and lower sides in FIG. 17 are opposite to upper and lower sides of the socket 10 as indicated by coordinate axes. In order to facilitate identification, the pin plate 50B is hatched.

The tapered portion 57a whose normal is obliquely upward and outward (obliquely downward and outward during pressing) and a step portion 57b are provided at a tip end portion of the engagement hook portion 57B. When the relative positions of the pin block 30B and the pin plate 50B are aligned with each other, the tapered portion 57a of the engagement hook portion 57B is abutted against a surface of the tapered portion 37b of the engagement protrusion portion 37B so as to face thereto. When the operator presses the pin plate 50B against the pin block 30B, a base of the engagement hook portion 57B starts to be bent due to elasticity, and the state shown in FIG. 17 is obtained.

FIG. 18 is an enlarged perspective cross-sectional view around the engagement hook portion 57B and the engagement protrusion portion 37B showing a state where assembly of the pin plate 50B to the pin block 30B is completed. The up-down direction and the hatching of the pin plate 50B are the same as those in FIG. 17.

Subsequent to FIG. 17, when the operator presses the pin plate 50B against the pin block 30B, the engagement protrusion portion 37B is bent due to elasticity thereof toward the gap 38 provided outside the engagement hole 36B. Then, a portion where the tapered portion 57a and the tapered portion 37b are abutted against each other slides, and thus the tapered portion 57a rides on the step portion 37c of the engagement protrusion portion 37B while bending of the engagement hook portion 57B is released. In the state shown in FIG. 18, the tapered portion 57a passes below the step portion 37c of the engagement protrusion portion 37B.

On the other hand, since the tapered portion 57a rides on the step portion 37c of the engagement protrusion portion 37B, a force applied to the tapered portion 57a is also removed, so that the bending of the engagement protrusion portion 37B is also released to return to an original free state.

As a result, the step portion 57b of the engagement hook portion 57B is hooked on the step portion 37c of the engagement protrusion portion 37B. As a result, the engagement protrusion portion 37B and the engagement hook portion 57B function as the engagement portion 60 that engages the pin block 30B and the pin plate 50B with each other.

When detaching the pin plate 50B from the pin block 30B, the operator tilts the engagement protrusion portion 37B toward the gap 38 and releases the engagement state with the engagement hook portion 57B. Then, the engagement hook portion 57B may be lifted and detached.

### Third Embodiment

A third embodiment to which the present invention is applied will be described. The same constituent elements as those of the first and second embodiments are denoted by the same reference numerals as those of the first and second embodiments, and redundant description thereof will be omitted.

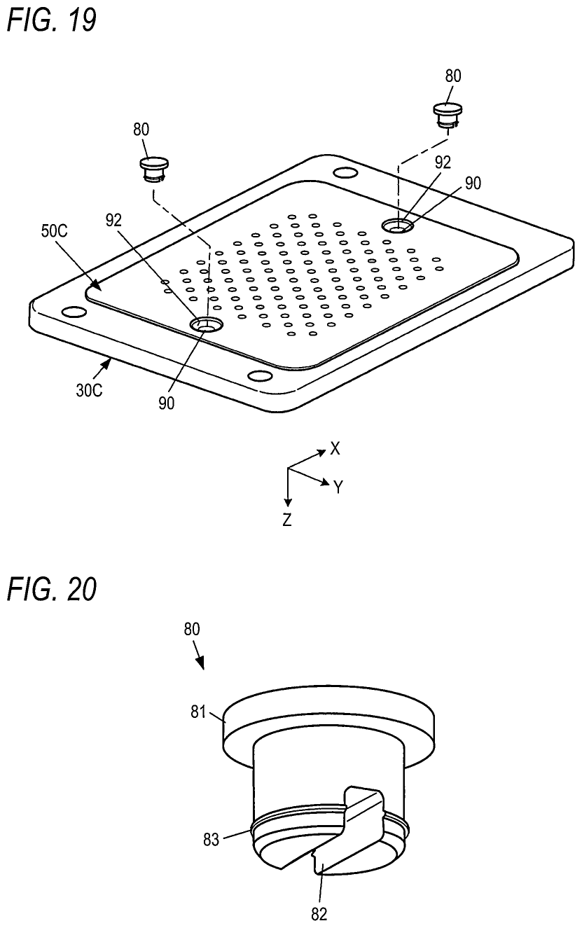

FIG. 19 is a perspective view showing a configuration example of a pin block 30C and a pin plate 50C according to the third embodiment. In FIG. 19, the pin block 30C and the pin plate 50C are shown with bottom surfaces thereof facing upward.

The socket 10 of the third embodiment includes the pin block 30C instead of the pin block 30 of the first embodiment, and includes the pin plate 50C instead of the pin plate 50 of the first embodiment.

The pin block 30C and the pin plate 50C are connected via a press-fit pin 80. However, in the state shown in FIG. 19, the pin plate 50C is attached to the pin block 30C while the press-fit pin 80 is not yet attached.

FIG. 20 is a perspective external view showing a configuration example of the press-fit pin 80. The press-fit pin 80 is a component made of an insulating elastic resin. The press-fit pin 80 includes a flange portion 81 at one end of an axis thereof, and includes a groove portion 82 along a radial direction in the other end that corresponds to a tip end of the pin. An annular protrusion 83 is formed along a peripheral direction on an outer periphery in the vicinity of the tip end of the axis of the press-fit pin 80.

Referring back to FIG. 19, similarly to the pin block 30 of the first embodiment and the pin block 30B of the second embodiment, the pin block 30C includes the plurality of probe insertion portions 32 in a bottom portion of the central recessed portion 31 (in FIG. 19, the probe insertion portions 32 are hidden by the pin plate 50C and are not seen). The pin block 30C includes block-side press-fit holes 90 for press-fitting the press-fit pin 80 at respective positions on the X-axis positive side and the X-axis negative side in an outer edge portion of the central recessed portion 31.

Similarly to the pin plate 50 of the first embodiment arid the pin plate 50B of the second embodiment, the pin plate 50C includes the plurality of probe insertion portions 54 in a ceiling portion of the central recessed portion 53. In FIG. 19, the central recessed portion 53 is located on a back side, and thus is hidden and not seen. The pin plate 50C also includes plate-side press-fit holes 92 for press-fitting the press-fit pin 80 at respective positions on the X-axis positive side and the X-axis negative side in an outer edge portion of the central recessed portion 53.

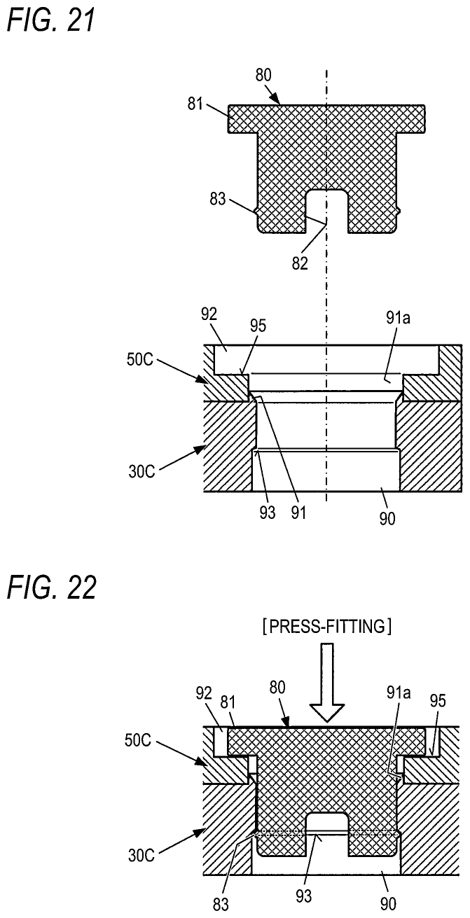

FIG. 21 is an enlarged cross-sectional view showing a connection portion between each block-side press-fit hole 90 and each plate-side press-fit hole 92. A positioning portion 91 is provided on the side of the pin plate 50C in the block-side press-fit hole 90. The positioning portion 91 is, for example, a convex portion formed by annularly protruding a periphery of an opening portion of the block-side press-fit hole 90.

An inner surface of the positioning portion 91 is formed with a tapered portion 91a whose diameter increases toward an opening end (end portion on the side of the pin plate 50C). An inner diameter of the opening end of the tapered portion 91a is set to be larger than an outer diameter of the protrusion 83 of the press-fit pin 80 in a free state.

The block-side press-fit hole 90 includes a step portion 93 at an intermediate position of the hole, the step portion 93 having an inner diameter slightly larger than the outer diameter of the protrusion 83 of the press-fit pin 80.

The plate-side press-fit hole 92 includes a step portion 95. An opening diameter and an inner diameter of a large-diameter portion of the step portion 95 match an outer diameter of the flange portion 81 of the press-fit pin 80. An inner diameter of a small diameter portion of the step portion 95 is set to achieve fitting that functions as positioning relative to an outer diameter of the positioning portion 91.

FIG. 22 is an enlarged cross-sectional view showing the connection portion between the block-side press-fit hole 90 and the plate-side press-fit hole 92, which shows a state where the press-fit pin 80 is press-fitted, engaged and fixed into the pin block 30C and the pin plate 50C that are subjected to positioning.

The operator attaches the pin plate 50C to the pin block 30C by covering and fitting the plate-side press-fit hole 92 onto the positioning portion 91. As a result, the block-side press-fit hole 90 and the plate-side press-fit hole 92 are positioned at appropriate relative positions, and form a continuous hole along the up-down direction.

Next, the operator inserts and press-fits a tip end of the press-fit pin 80 including the groove portion 82 from the plate-side press-fit hole 92. When the protrusion 83 is abutted against the tapered portion 91a, a side portion of the groove portion 82 is elastically deformed and squeezed, and thus the press-fit pin 80 is press-fitted. When the flange portion 81 of the press-fit pin 80 is abutted against the step portion 95 of the plate-side press-fit hole 92, the protrusion 83 reaches the step portion 93 of the block side press-fit hole 90. Then, the squeezing deformation of the side portion of the groove portion 82 is loosened, and a part of the elastic deformation generated at the end portion is released. Then, the protrusion 83 is engaged with the step portion 93, and the press-fit pin 80 is brought into pressure contact with an inner surface of the block-side press-fit hole 90. Thus, assembly of the pin plate 50C to the pin block 30C is completed.

In order to detach the pin plate 50C from the pin block 30C, the operator pushes and pulls out the tip end portion of the press-fit pin 80 from a side of the block-side press-fit hole 90.

### Summary

The disclosure of the present specification can be summarized as follows.

According to an aspect of the present disclosure, a socket includes a pin block on which a plurality of contact probes are installed, a pin plate configured to hold the plurality of contact probes together with the pin block, and an engagement portion configured to engage the pin block and the pin plate with each other.

According to this aspect, a contact probe holding structure adapted to thickness reduction of the socket can be achieved.

The engagement portion is configured to detachably engage the pin block and the pin plate with each other.

As a result, components such as the pin block, the pin plate, and the contact probes can be easily rearranged and repaired.

The pin block includes a positioning portion configured to position the pin plate, and the engagement portion is configured to engage the pin plate positioned by the positioning portion with the pin block.

As a result, workability and assembly accuracy of assembling the pin plate to the pin block can be improved.

The engagement portion includes an engagement hook portion formed on the pin plate and an engagement protrusion formed on the pin block, and the engagement hook portion and the engagement protrusion are configured to be engaged with each other so as to attach the pin plate to the pin block.

As a result, the engagement can be reliably achieved even with a simple configuration.

At least a part of the pin plate has elasticity.

At least a part of the pin plate has elasticity, and the elasticity is used to engage the engagement hook portion and the engagement protrusion with each other.

As a result, the engagement can be maintained by using bending due to the elasticity. Further, work feeling can be clarified due to resistance feeling when the bending occurs most in the assembly and sound generated when the bending is released, and thus workability can be improved.

The pin plate includes an inner region portion provided with a through hole through which the plurality of contact probes pass, and an outer region portion that includes the engagement hook portion and has the elasticity.

As a result, by inducing the bending caused by the engagement on the outer region portion, bending of the inner region portion into which the contact probe is inserted is prevented, it is possible to prevent an event when the contact probe comes into contact with the pin plate at the time of assembly and applies an excessive force, and thus the assembly accuracy can be improved.

The outer region portion includes a loop-shaped ear portion connected to the inner region portion.

As a result, the inner region portion is more unlikely to be bent.

The ear portion includes: a linear portion that is the engagement hook portion; and a flexible portion that is configured to exhibit the elasticity, and the ear portion is connected to the inner region portion via the flexible portion.

As a result, the flexible portion can handle occurrence of bending at once and prevent bending at the engagement hook portion. Since it is not necessary to consider the bending of the engagement hook portion, dimensions of the engagement hook portion and the engagement protrusion portion can be reduced, and thus downsizing of the socket can be promoted.

The outer region portion includes a pair of the ear portions with the inner region portion interposed therebetween.

As a result, occurrence of bending at the inner region portion can be effectively prevented.

The pin block includes an engagement claw portion at a tip end portion of the engagement protrusion, and the engagement hook portion is configured to be pressed in a state of being abutted against the engagement claw portion so as to be engaged with the engagement claw portion.

As a result, the pin block and the pin plate can be easily assembled.

The engagement claw portion includes a tapered portion, and the engagement hook portion is configured to be pressed in a state of being abutted against the tapered portion so as to move along the tapered portion and engage with the engagement claw portion.

As a result, the pin block and the pin plate can be easily assembled.

The pin plate includes a press-fit hole, the engagement portion includes a step portion provided in the press-fit hole and a protrusion formed on a press-fit pin, and the protrusion of the press-fit pin press-fitted into the press-fit hole is configured to be engaged with the step portion so as to attach the pin plate to the pin block.

As a result, the pin plate and the pin block can be engaged and fixed by the press-fit pin.

A tool used when assembling the socket of the present aspect is a tool in which the pin plate is held by applying a load to a predetermined portion of the pin plate to elastically deform a portion of the pin plate having the elasticity, and a holding of the pin plate is released by releasing the load.

By using this tool, assembly accuracy can be improved.

The tool includes: a pair of tip end portions configured to be abutted against the pair of ear portions; a pair of handles; a fulcrum configured to cause a force that reduces a distance between the pair of handles to be applied as a force that widens a distance between the pair of tip end portions; and an urging portion configured to urge the pair of handles in a direction in which the distance therebetween is widened.

With this tool, assembly can be performed with simple work.

The tool further includes a limiting portion configured to limit an approaching distance between the pair of handles.

As a result, it is possible to prevent an excessive load from being applied to the pin plate.

### REFERENCE SIGNS LIST

10 . . . socket

28 . . . contact probe array

30, 30B, 30C . . . pin block

32 . . . probe insertion portion

33, 33B . . . positioning portion

37, 37B . . . engagement protrusion portion

37a . . . engagement claw portion

37b . . . tapered portion

50, 50B, 50C . . . pin plate

51 . . . inner region portion

52 . . . outer region portion

54 . . . probe insertion portion

57, 57B . . . engagement hook portion

57a . . . tapered portion

57b . . . step portion

58 . . . flexible portion

60 . . . engagement portion

80 . . . press-fit pin

83 . . . protrusion

90 . . . block-side press-fit hole

92 . . . plate-side press-fit hole

100 . . . tool

101 . . . handle

102 . . . fulcrum shaft

103 . . . tip end portion

114 . . . first abutment surface

116 . . . second abutment surface (limiting portion)

120 . . . urging portion

1. A socket comprising:
a pin block on which a plurality of contact probes are installed;
a pin plate configured to hold the plurality of contact probes together with the pin block; and
an engagement portion configured to engage the pin block and the pin plate with each other.

2. The socket according to claim 1, wherein the engagement portion is configured to detachably engage the pin block and the pin plate with each other.

3. The socket according to claim 1, wherein the pin block includes a positioning portion configured to position the pin plate, and
the engagement portion is configured to engage the pin plate positioned by the positioning portion with the pin block.

4. The socket according to claim 1, wherein the engagement portion includes an engagement hook portion formed on the pin plate and an engagement protrusion formed on the pin block, and
the engagement hook portion and the engagement protrusion are configured to be engaged with each other so as to attach the pin plate to the pin block.

5. The socket according to claim 1, wherein at least a part of the pin plate has elasticity.

6. The socket according to claim 4, wherein at least a part of the pin plate has elasticity, and
the elasticity is used to engage the engagement hook portion and the engagement protrusion with each other.

7. The socket according to claim 6, wherein the pin plate includes an inner region portion provided with a through hole through which the plurality of contact probes pass, and an outer region portion that includes the engagement hook portion and has the elasticity.

8. The socket according to claim 7, wherein the outer region portion includes a loop-shaped ear portion connected to the inner region portion.

9. The socket according to claim 8, wherein the ear portion includes:
a linear portion that is the engagement hook portion; and
a flexible portion that is configured to exhibit the elasticity, and
the ear portion is connected to the inner region portion via the flexible portion.

10. The socket according to claim 8, wherein the outer region portion includes a pair of the ear portions with the inner region portion interposed therebetween.

11. The socket according to claim 4, wherein the pin block includes an engagement claw portion at a tip end portion of the engagement protrusion, and
the engagement hook portion is configured to be pressed in a state of being abutted against the engagement claw portion so as to be engaged with the engagement claw portion.

12. The socket according to claim 1 wherein the engagement claw portion includes a tapered portion, and
the engagement hook portion is configured to be pressed in a state of being abutted against the tapered portion so as to move along the tapered portion and engage with the engagement claw portion.

13. The socket according to claim 1, wherein the pin plate includes a press-fit hole,
the engagement portion includes a step portion vided in the press-fit hole and a protrusion formed on a press-fit pin, and
the protrusion of the press-fit pin press-fitted into the press-fit hole is configured to be engaged with the step portion so as to attach the pin plate to the pin block.

14. A tool used when assembling the socket according to claim 5,
wherein the pin plate is held by applying a load to a predetermined portion of the pin plate to elastically deform a portion of the pin plate having the elasticity, and a holding of the pin plate is released by releasing the load.

15. A tool used when assembling the socket according to claim 10, comprising:
a pair of tip end portions configured to be abutted against the pair of ear portions;
a pair of handles;
a fulcrum configured to cause a force that reduces a distance between the pair of handles to be applied as a force that widens a distance between the pair of tip end portions; and
an urging portion configured to urge the pair of handles in a direction in which the distance therebetween is widened.

16. The tool according to claim 15, further comprising:
a limiting portion configured to limit an approaching distance between the pair of handles.
